(19) United States
(12) Patent Application Publication
(10) Pub. No.: US 2007/0194318 A1
(43) Pub. Date: Aug. 23, 2007

(54) ORGANIC LIGHT EMITTING DIODE DISPLAY

(75) Inventors: Kwang-Chul JUNG, Seongnam-si (KR); Beohm-Rock CHOI, Seoul (KR); Chun-Seok KO, Hwaseong-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD, Suwon-si (KR)

(21) Appl. No.: 11/619,834

(22) Filed: Jan. 4, 2007

(30) Foreign Application Priority Data
Feb. 20, 2006 (KR) 10-2006-0016177

(51) Int. Cl. H01L 29/04; H01L 29/08; H01L 33/00; G09G 3/32

(52) U.S. Cl. 257/72; 257/40; 257/103; 345/82

(57) ABSTRACT

The present invention relates to an organic light emitting diode display having an optical film adhered to an outer surface of substrate and an external case covering a portion of the optical film so as to prevent display quality of the organic light emitting diode display from being degraded. The present invention makes it possible to safely protect an organic light emitting diode display since an impact is not directly delivered to the insulation substrate from the outside, but is delivered after being first absorbed by the optical film exposed to the outside.

This application claims priority to Korean Patent Application No. 10-2006-016177, filed on Feb. 20, 2006, and all the benefits accruing therefrom under 35 U.S.C. §119, the contents of which in its entirety are herein incorporated by reference.

### BACKGROUND OF THE INVENTION

(a) Field of the Invention

The present invention relates to an organic light emitting diode display.

(b) Description of the Related Art

In recent years, lightweight and thin monitors or televisions have become required, and liquid crystal displays (“LCDs”) satisfying this requirement are being substituted for conventional cathode ray tubes (“CRTs”). However, since the liquid crystal display is a light receiving/emitting device, the liquid crystal display requires a backlight and has many problems including a slow response speed and limited viewing angle compared to the conventional CRT.

In recent years, an organic light emitting diode display has attracted attention as a display device due to its capability of solving the above-described problems. The organic light emitting diode display includes two electrodes and a light emitting layer positioned therebetween. Electrons injected from one electrode and holes injected from the other electrode are combined in the light emitting layer so as to form excitons, and the excitons emit light through energy emission.

Since the organic light emitting diode display is a self-emitting type, it does not need an additional light source, e.g., a backlight. Therefore, the organic light emitting diode display has low power consumption, as well as excellent response speed, viewing angle and contrast ratio.

The organic light emitting diode display may be classified as either a passive organic light emitting diode display or an active organic light emitting diode display. The passive organic light emitting diode display has a simple structure where light is emitted from a region where the two electrodes cross each other. The active organic light emitting diode display has a structure in which light is emitted by current-driving a thin film transistor (“TFT”) for each pixel.

According to the light emitting structure, the active organic light emitting diode display is classified as either a bottom emission structure in which light is emitted toward a substrate on which thin film transistors are formed, and a top emission structure in which light is emitted from a side opposite to the substrate on which the thin film transistors are formed.

In these organic light emitting diode displays, display quality is degraded due to reflection of external light.

### BRIEF SUMMARY OF THE INVENTION

An exemplary embodiment of the present invention provides an organic light emitting diode display including: a first substrate; first signal lines formed on the first substrate; second signal lines formed on the first substrate; switching thin film transistors connected to the first and second signal lines; driving thin film transistors connected to the switching thin film transistors; organic light emitting diodes connected to the driving thin film transistors; a second substrate covering the organic light emitting diodes; an optical film adhered to an outer surface of the first substrate or the second substrate; and an external case covering a portion of the optical film.

The optical film is a film having low reflectance.

The optical film may be two or more films formed in multiple layers.

An adhesive is interposed between the optical film and the substrate adhered to the optical film.

the optical film comprises a circular polarizer.

light emitted in the organic light emitting diodes passes through the substrate adhered to the optical film.

two or more organic light emitting diodes form a light emitting region where an image is displayed and the optical film is formed covering the light emitting region, and wherein the external case has an opening having an area larger than an area of the light emitting region and smaller than an area of the optical film.

Another exemplary embodiment of the present invention provides an organic light emitting diode display including: a first substrate; first signal lines formed on the first substrate; second signal lines formed on the first substrate; switching thin film transistors connected to the first and second signal lines; driving thin film transistors connected to the switching thin film transistors; organic light emitting diodes connected to the driving thin film transistors,; a second substrate covering the organic light emitting diodes; an optical film adhered to an upper surface of the second substrate; and an external case covering a portion of the optical film.

The optical film is a film having low reflectance.

The optical film has two or more films formed in multiple layers.

The second substrate and the optical film are adhered by an adhesive.

Each of the organic light emitting diodes includes a first electrode including a transparent conductive material on the light emitting side surface, a second electrode including a reflective metal on a side surface opposite to the light emitting side surface, and a light emitting member formed between the first electrode and the second electrode.

Two or more organic light emitting diodes form a light emitting region where an image is displayed and the optical film is formed covering the light emitting region.

The external case has an opening having an area larger than an area of the light emitting region and smaller than an area of the optical film.

Another exemplary embodiment of the present invention provides an organic light emitting diode display including: a first substrate; first signal lines formed on the first substrate; second signal lines formed on the first substrate; switching thin film transistors connected to the first and second signal lines; driving thin film transistors connected to the switching thin film transistors; first electrodes connected to the driving thin film transistors; second electrodes facing the first electrodes; light emitting members respectively formed between the first electrodes and the second electrodes; a light emitting region in which the plurality of first electrodes, second electrodes, and light emitting members are formed so as to display images; an optical film adhered to the bottom of the first substrate; and an external case having an opening, wherein the external case covers a portion of the optical film.

The opening is formed so as to expose the optical film.

The opening is larger than an area of the light emitting region and smaller than an area of the optical film.

The optical film is a film having low reflectance.

The optical film has two or more films formed in multiple layers.

The first substrate and the optical film are adhered by an adhesive.

### BRIEF DESCRIPTION OF THE DRAWINGS

The present invention will become more apparent by further describing exemplary embodiments thereof with reference to the accompanying drawings, in which:

FIG. 1 is an equivalent circuit schematic diagram of an exemplary embodiment of an organic light emitting diode display according to the present invention;

FIG. 2 is a plan view layout of the exemplary embodiment of an organic light emitting diode display of FIG. 1 according to the present invention;

FIGS. 3 and 4 are cross-sectional views of the organic light emitting diode display shown in FIG. 2 taken along lines III-III and IV-IV, respectively;

FIGS. 5 and 6 are cross-sectional views of the organic light emitting diode display shown in FIG. 2 taken along lines III-III and IV-IV, respectively;

FIG. 7 is a plan view layout of an exemplary embodiment of an organic light emitting diode display illustrating the relationship among the sizes of a light emitting region, a case and an optical film according to the present invention;

FIG. 8 is a cross-sectional view of an exemplary bottom emission type organic light emitting diode display shown in FIG. 7 taken along line VI-VI according to an exemplary embodiment of the present invention; and

FIG. 9 is a cross-sectional view of an exemplary top emission type organic light emitting diode display shown in FIG. 7 taken along line VI-VI according to another embodiment of the present invention.

### DETAILED DESCRIPTION OF THE INVENTION

The present invention has an advantage of improving display quality by preventing external light from being reflected. The present invention also provides an advantage of forming a wider region for protecting the organic light emitting diode display.

In order to achieve the above-described advantages, in an exemplary embodiment of the present invention, an optical film is formed on an entire opening of an external case such that the size of the opening of the external case is larger than that of a light emitting region and smaller than that of the optical film. Therefore, it is possible to prevent external light generated between the light emitting region and the opening of the external case from being reflected.

The present invention will now be described more fully hereinafter with reference to the accompanying drawings, in which exemplary embodiments of the present invention are shown. This invention may, however, be embodied in many different forms and should not be construed as limited to the exemplary embodiments set forth herein.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present invention.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises” and/or “comprising” or “includes” and/or “including” when used in this specification specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein may be interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention. As used herein, the term “and/or” includes any and all combinations of one or more of the associated listed items.

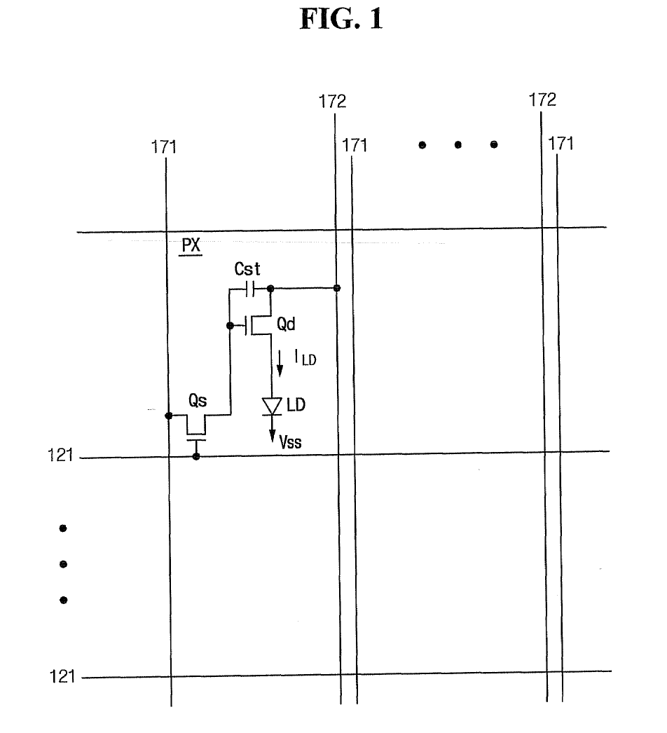

First, an exemplary embodiment of an organic light emitting diode display according to the present invention will be described in more detail with reference to FIG. 1. FIG. 1 is an equivalent circuit schematic diagram of an organic light emitting diode display according to an exemplary embodiment of the present invention.

Referring to FIG. 1, the exemplary organic light emitting diode display according to the present invention includes a plurality of signal lines 121, 171 and 172, and a plurality of pixels PX connected to the signal lines 121, 171 and 172 and are substantially arranged in a matrix shape. The signal lines include a plurality of gate lines 121 which transmit gate signals (or scanning signals), a plurality of data lines 171 which transmit data signals and a plurality of driving voltage lines 172 which transmit a driving voltage. The gate lines 121 extend substantially in a row direction in parallel with one another, and the data lines 171 and the driving voltage lines 172 extend substantially in a column direction in parallel with one another, as illustrated.

Each of the pixels PX includes a switching transistor Qs, a driving transistor Qd, a storage capacitor Cst and an organic light emitting diode LD. The switching transistor Qs includes a control terminal, an input terminal and an output terminal. The control terminal is connected to the gate line 121, the input terminal is connected to the data line 171 and the output terminal is connected to the driving transistor Qd. The switching transistor Qs transmits a data signal, which is applied from the data line 171, to the driving transistor Qd in response to the scanning signal applied to the gate line 121.

The driving transistor Qd includes a control terminal, an input terminal and an output terminal. The control terminal is connected to the switching transistor Qs, the input terminal is connected to the driving voltage line 172 and the output terminal is connected to the organic light emitting diode LD. The driving transistor Qd outputs an output current I_{LD}, whose magnitude varies according to a voltage between the control terminal and the output terminal.

The capacitor Cst is connected between the control terminal and the input terminal of the driving transistor Qd. The capacitor Cst charges the data signal supplied to the control terminal of the driving transistor Qd and holds the data signal even though the switching transistor Qs is turned off.

The organic light emitting diode LD has an anode connected to the output terminal of the driving transistor Qd and a cathode connected to a common voltage Vss. The organic light emitting diode LD displays an image by emitting light at a different intensity according to the output current I_{LD} of the driving transistor Qd.

The switching transistor Qs and the driving transistor Qd are n-channel field effect transistors (“FETs”). However, at least one of the switching transistor Qs and the driving transistor Qd may be a p-channel field effect transistor. Further, the connection relationship among the transistors Qs and Qd, the capacitor Cst and the organic light emitting diode LD may be changed in alternative exemplary embodiments.

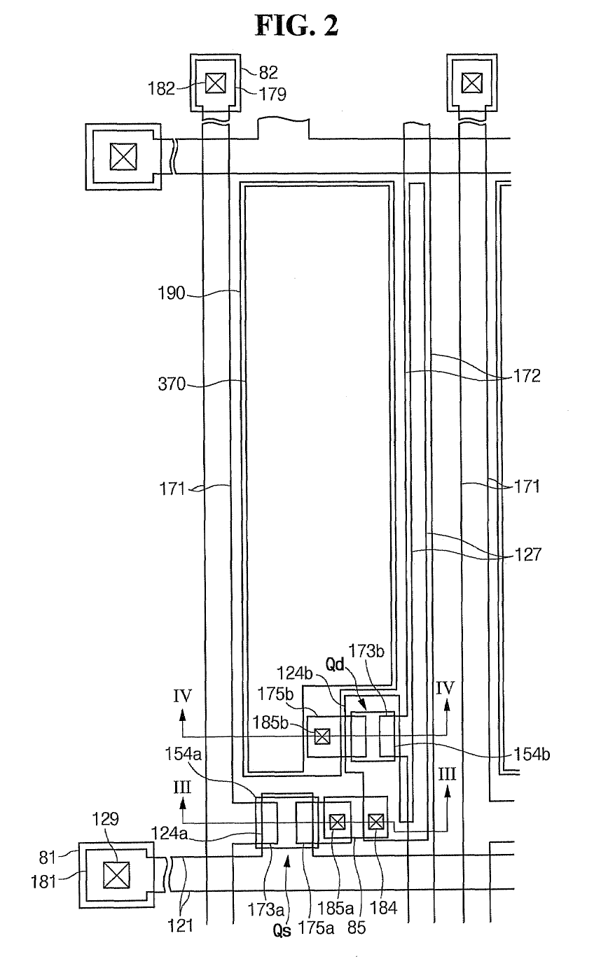

Hereinafter, the structure of the exemplary organic light emitting diode display shown in FIG. 1 will be described in more detail with reference to FIGS. 2 to 4.

FIGS. 2 to 4 show the organic light emitting diode display of a bottom emission type according to an exemplary embodiment of the present invention.

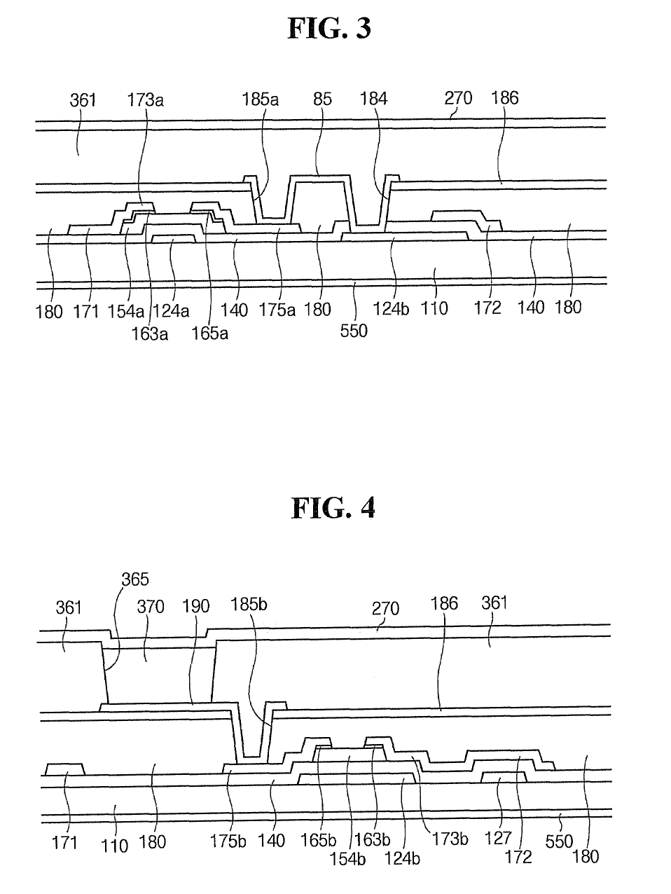

FIG. 2 is a plan view layout view of the organic light emitting diode display according to an exemplary embodiment of the present invention, and FIGS. 3 and 4 are cross-sectional views of the organic light emitting diode display shown in FIG. 2 taken along lines III-III and IV-IV, respectively.

A plurality of gate conductors which include a plurality of gate lines 121 having first control electrodes 124a, and second control electrodes 124b are provided on an insulation substrate 110 formed of transparent glass or plastic.

The gate lines 121 transmit the gate signals and extend in the horizontal direction, as illustrated in FIG. 2. Each of the gate lines 121 includes a wider end portion 129 for connection to a different layer or an external driving circuit (not shown). The first control electrodes 124a extend upward from the gate lines 121, as illustrated in FIG. 2. When a gate driving circuit (not shown) which generates the gate signals is integrated on the substrate 110, the gate lines 121 may extend to be directly connected to the gate driving circuit.

The second control electrodes 124b are separated from the gate lines 121, and have storage electrodes 127 that extend downward, turn right, and then extend upward, as illustrated in FIG. 2.

The gate conductors 121 and 124b may be formed of an aluminum-based metal, such as aluminum (Al) or an aluminum alloy, a silver-based metal, such as silver (Ag) or a silver alloy, a copper-based metal, such as copper (Cu) or a copper alloy, a molybdenum-based metal, such as molybdenum (Mo) or a molybdenum alloy, chromium (Cr), tantalum (Ta), or titanium (Ti). However, each of the gate conductors 121 and 124b may have a multi-layered structure which includes two conductive layers (not shown) having different physical properties.

A side surface of each of the gate conductors 121 and 124b is inclined with respect to a surface of the substrate 110, and the inclination angle is desirably in a range of about 30° to about 80°.

A gate insulating layer 140 formed of silicon nitride (“SiNₓ”) or silicon oxide (“SiOₓ”) is formed on the gate conductors 121 and 124b. A plurality of first and second semiconductor islands 154a and 154b, respectively, formed of hydrogenated amorphous silicon (simply referred to as “a-Si”) or polysilicon, are formed on the gate insulating layer 140. The first and second semiconductor islands 154a and 154b are positioned on the first and second control electrodes 124a and 124b, respectively.

A plurality of pairs of first ohmic contacts 163a and 165a and a plurality of pairs of second ohmic contacts 163b and 165b are formed on the first and second semiconductor islands 154a and 154b, respectively. The ohmic contacts 163a, 163b, 165a and 165b have island shapes and may be formed of a material, such as n+ hydrogenated amorphous silicon, in which an n-type impurity, such as phosphorus, is doped with high concentration, or silicide. The first ohmic contacts 163a and 165a are disposed on the first semiconductor islands 154a in pairs, and the second ohmic contacts 163b and 165b are disposed on the second semiconductors 154b in pairs.

A plurality of data conductors which include a plurality of data lines 171, a plurality of driving voltage lines 172, and a plurality of first and second output electrodes 175a and 175b are formed on the ohmic contacts 163a, 163b, 165a and 165b and the gate insulating layer 140.

The data lines 171 transmit data signals and substantially extend in a vertical direction so as to cross the gate lines 121, as illustrated in FIG. 2. Each of the data lines 171 includes a plurality of first input electrodes 173a which extend toward the first control electrode 124a and a wider end portion 179, as illustrated in FIG. 2, for connection to a different layer or an external driving circuit (not shown). When a data driving circuit (not shown) which generates the data signals is integrated on the substrate 110, the data lines 171 may extend to be directly connected to the data driving circuit.

The driving voltage lines 172 transmit the driving voltage and substantially extend in the vertical direction so as to cross the gate lines 121, as illustrated in FIG. 2. Each of the driving voltage lines 172 includes a plurality of the second input electrodes 173b that extend toward the second control electrodes 124b. The driving voltage lines 172 overlap the storage electrodes 127 and may be connected to each other.

The first and second output electrodes 175a and 175b are separated from each other. Further, the first and second output electrodes 175a and 175b are separated from the data lines 171 and the driving voltage lines 172. The first input electrodes 173a and the first output electrodes 175a face each other with the first control electrodes 124a interposed therebetween, and the second input electrodes 173b and the second output electrodes 175b face each other with the second control electrodes 124b interposed therebetween.

The data conductors 171, 172, 175a and 175b are preferably formed of a refractory metal, such as molybdenum, chromium, tantalum, or titanium, or an alloy thereof. The data conductors 171, 172, 175a and 175b may have a multi-layered structure formed of a refractory metal (not shown) and a low-resistance material conductive layer (not shown).

Like the gate conductors 121 and 124b, side surfaces of each of the data conductors 171, 172, 175a and 175b are desirably inclined at an inclination angle of about 30° to about 80° with respect to the surface of the substrate 110.

The ohmic contacts 163a, 163b, 165a and 165b are provided only between the underlying semiconductor islands 154a and 154b and the overlying data conductors 171, 172, 175a and 175b so as to reduce contact resistance therebetween. The semiconductor islands 154a and 154b have exposed portions which are not covered with the data conductors 171, 172, 175a and 175b, including portions between the input electrodes 173a and 173b and the output electrodes 175a and 175b.

A passivation layer 180 is formed on the data conductors 171, 172, 175a and 175b and the exposed portions of the semiconductor islands 154a and 154b. The passivation layer 180 is formed of an inorganic insulator, such as silicon nitride or silicon oxide, an organic insulator, or a low-dielectric-constant insulator. The dielectric constant of the organic insulator and the low-dielectric-constant insulator is desirably 4.0 or less, and, for example, a-Si:C:O or a-Si:O:F which is formed by a plasma enhanced chemical vapor deposition (“PECVD”) method is used. The passivation layer 180 may be formed of a material having photosensitivity among the organic insulators, and a surface of the passivation layer 180 may be planarized. The passivation layer 180 may have a double-layered structure of a lower inorganic layer and an upper organic layer so as to use the excellent insulating characteristics of an organic layer and to prevent the exposed portions of the semiconductor islands 154a and 154b from being damaged.

A plurality of contact holes 182, 185a and 185b are formed in the passivation layer 180 so as to expose the end portions 179 of the data lines 171 and the first and second output electrodes 175a and 175b, respectively. Further, a plurality of contact holes 181 and 184 are formed in the passivation layer 180 and the gate insulating layer 140 so as to expose the end portions 129 of the gate lines 121 and the second input electrodes 124b, respectively.

A plurality of pixel electrodes 190, a plurality of connecting members 85 and a plurality of contact assistants 81 and 82 are formed on the passivation layer 180. They may be formed of a transparent conductive material, such as indium tin oxide (“ITO”) or indium zinc oxide (“IZO”). The pixel electrodes 190 are physically and electrically connected to the second output electrodes 175b through the contact holes 185b, and the connecting members 85 are connected to the second control electrodes 124b and the first output electrodes 175a through the contact holes 184 and 185a, respectively.

The contact assistants 81 and 82 are connected to the end portions 129 of the gate lines 121 and the end portions 179 of the data lines 171 through the contact holes 181 and 182, respectively. The contact assistants 81 and 82 assist adhesion of the end portions 179 and 129 of the data lines 171 and the gate lines 121 to an external device (not shown) and protect the end portions 179 and 129.

A partition 361 is formed on the passivation layer 180. The partition 361 defines openings 365 by surrounding an edge of the pixel electrodes 190 in a bank shape, and is formed of an organic insulator or an inorganic insulator. The partition 361 may be formed of photoresist including a black pigment. In this case, the partition 361 serves as a light blocking member. A process of forming the partition 361 is simply performed.

Organic light emitting members 370 are formed in the openings 365 in the pixel electrodes 190 defined by the partition 361. The organic light emitting members 370 are formed of an organic material which uniquely emits light of one of three primary colors, such as red, green and blue, for example, but is not limited thereto. The organic light emitting diode (“OLED)” display displays desired images by a spatial sum of color light components of primary colors emitted by the organic light emitting members 370.

The organic light emitting members 370 may have a multi-layered structure including an auxiliary layer (not shown) for improving light-emission efficiency of the light emitting layer, in addition to the light emitting layer (not shown). The auxiliary layer includes an electron transport layer (not shown) and a hole transport layer (not shown) for balancing electrons and holes, and an electron injection layer (not shown) and a hole injection layer (not shown) for reinforcing the injection of the electrons and holes.

A common electrode 270 is formed on the organic light emitting member 370. The common electrode 270 is applied with the common voltage Vss and is formed of a reflective material, such as Ca, Ba, Mg, aluminum, or silver, for example.

In the organic light emitting diode (“OLED”) display, the first control electrode 124a connected to the gate line 121, the first input electrode 173a connected to the data line 171, and the first output electrode 175a form a switching thin film transistor Qs, together with the first semiconductor island 154a. A channel of the switching thin film transistor Qs is formed in the first semiconductor island 154a between the first input electrode 173a and the first output electrode 175a. A second control electrode 124b connected to the first output electrode 175a, the second input electrode 173b formed in the driving voltage line 172, and the second output electrode 175b connected to the pixel electrode 190 form a driving thin film transistor Qd, together with the second semiconductor island 154b. A channel of the driving thin film transistor Qd is formed in the second semiconductor island 154b between the second input electrode 173b and the second output electrode 175b. The pixel electrode 190, the organic light emitting member 370 and the common electrode 270 form the organic light emitting device LD. Here, the pixel electrode 190 serves as an anode, and the common electrode 270 serves as a cathode. In contrast, the pixel electrode 190 may serve as the cathode, and the common electrode 270 may serve as the anode. The second storage electrode 127 and the driving voltage line 172 which overlap each other form the storage capacitor Cst.

In the organic light emitting diode (“OLED”) display according to the present exemplary embodiment, the pixel electrode 190 is formed of a transparent electrode, such as ITO, and the common electrode 270 is formed of a nontransparent and reflective metal. That is, the organic light emitting diode (“OLED”) display according to the present exemplary embodiment is a bottom emission type organic light-emitting device display that displays images below the substrate 110.

On the bottom surface of the insulation substrate 110, a plurality of films, for example, a low-reflective film such as an anti-reflection film or anti-glare film, which allows light emitted from the organic light emitting members 370 to be clearly viewed, or a protective film, such as an anti-scratch film, which protects a polarizer and an organic light emitting diode display, can be formed. As a representative one, an optical film 550 is shown in the cross-sectional views of FIGS. 3 and 4. A plurality of films may form the optical film 550 by overlapping each other.

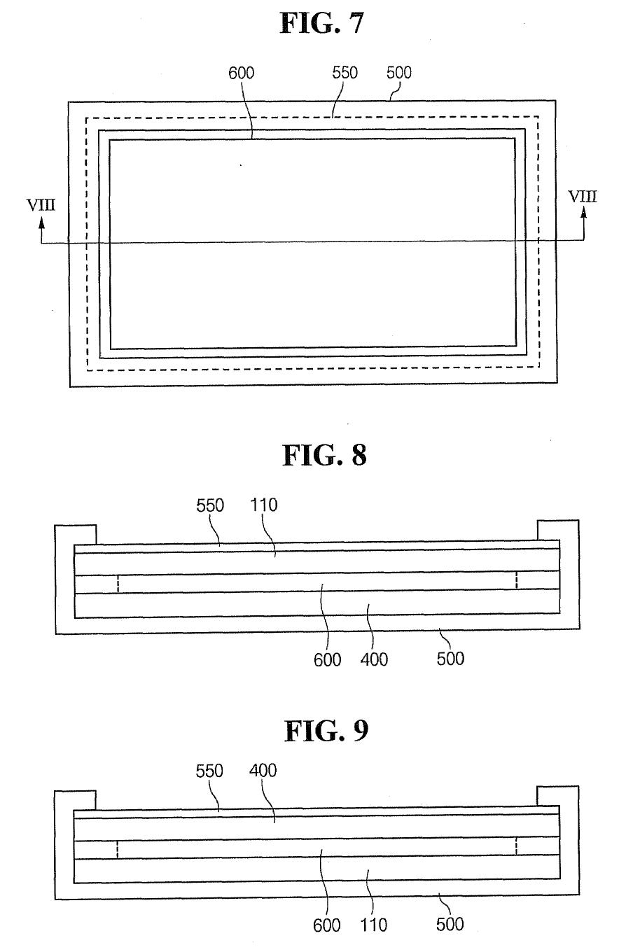

In the organic light emitting diode display, the optical film 550 is formed in a light emitting region where an image is actually displayed and the other regions. The range forming the optical film 550 will be described below with reference to FIGS. 7 and 8.

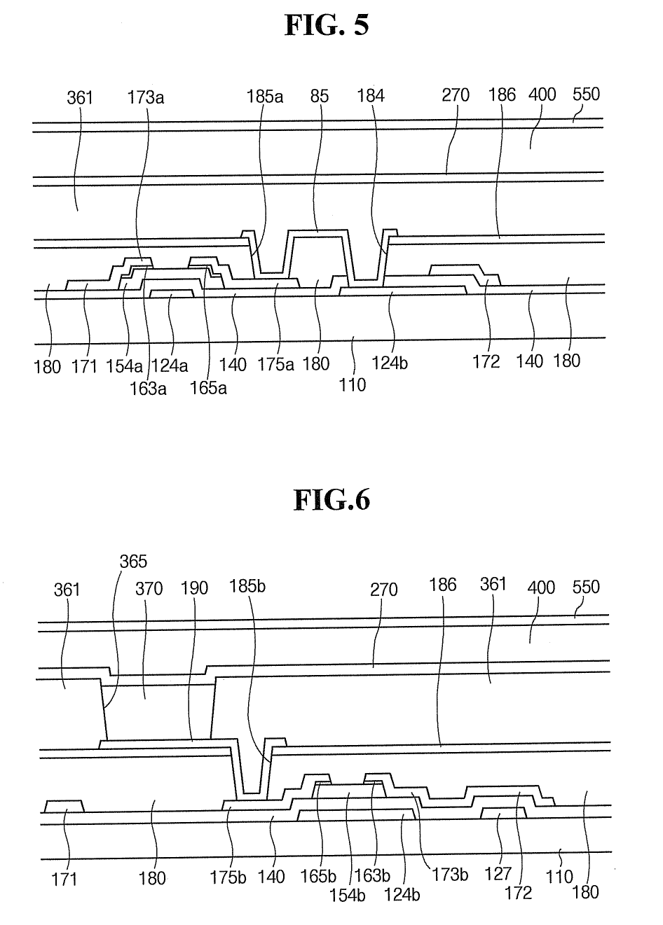

FIGS. 5 and 6 are cross-sectional views of an exemplary embodiment of a top emission type organic light emitting diode (“OLED”) display. The plan view layout to the present exemplary embodiment of FIGS. 5 and 6 is the same as in FIG. 2.

FIGS. 5 and 6 are cross-sectional views of the exemplary organic light emitting diode (“OLED”) display shown in FIG. 2 taken along lines III-III and IV-IV, respectively.

Unlike FIGS. 3 and 4, in FIGS. 5 and 6, the optical film 550 is not formed at the bottom surface of the insulation substrate 110, but is adhered to an upper portion of the insulation substrate 400 formed on the common electrode 270.

Further, for top emission, materials that form the common electrode 270 and the pixel electrodes 190 are different from those shown in FIGS. 3 and 4. That is, the pixel electrodes 190 are formed of a reflective metal, such as aluminum, silver, or an alloy thereof, and the common electrode 270 is formed of a transparent conductive material, such as ITO or IZO.

As shown in FIGS. 5 and 6, since a nontransparent pixel electrode 190 and a transparent common electrode 270 display an image above the substrate 110, it is called a top emission type organic light emitting diode display. In the top emission type organic light emitting diode display, in order to solve a problem that a predetermined voltage is not applied to the entire common electrode when the transparent common electrode 270 has high resistance, an additional wiring (not shown) formed of a low-resistance material is formed and the common voltage Vss is applied to the common electrode 270 at multiple positions. Therefore, the entire common electrode 270 can have a predetermined voltage.

As for the optical film 550, specifically, a plurality of films, for example, a low-reflective film such as an anti-reflection film or anti-glare film, which allows the light emitted from the organic light emitting member 370 to be clearly viewed, or a protective film, such as an anti-scratch film, which protects a polarizer and an organic light emitting diode display, can be formed on the upper surface of an upper insulation substrate 400. As a representative one, the optical film 550 is shown in FIGS. 5 and 6. The optical film 550 may have a plurality of films that are formed to overlap one another.

In the organic light emitting diode display, the optical film 550 is formed on a light emitting region where an image is actually displayed and on the other regions. The range in which the optical film 550 is formed will be described below with reference to FIGS. 7 and 8.

Unlike the above described exemplary embodiments, the bottom emission type or top emission type organic light emitting diode display shown in FIGS. 2 to 6 can have the following features.

When the semiconductor islands 154a and 154b are formed of polycrystalline silicon, an intrinsic region (not shown) which faces the control electrodes 124a and 124b and extrinsic regions (not shown) which are positioned on both sides of the intrinsic region are included. The extrinsic regions are electrically connected to the input electrodes 173a and 173b and the output electrodes 175a and 175b. The ohmic contacts 163a, 163b, 165a and 165b may be omitted.

Further, the control electrodes 124a and 124b may be formed on the semiconductor islands 154a and 154b, respectively. In this case, the gate insulating layer 140 is also positioned between the semiconductor islands 154a and 154b and the control electrodes 124a and 124b. At this time, the data conductors 171, 172, 173b and 175b are formed on the gate insulating layer 140 and electrically connected to the semiconductor islands 154a and 154b through contact holes (not shown) formed in the gate insulating layer 140. The data conductors 171, 172, 173b and 175b may be formed under the semiconductor islands 154a and 154b and electrically connected to the semiconductor islands 154a and 154b.

Hereinafter, FIGS. 7 to 9 show the relationship among the sizes of a light emitting region 600, the optical film 550, and an external case 500 according to the exemplary embodiment of the present invention.

The external case 500 has characteristics of protecting the organic light emitting diode display and defining an external shape of the organic light emitting diode display so as to attract a user's attention with excellent design. An opening is formed at the front surface of the external case 500, and the light emitting region 600 of the organic light emitting diode display is positioned within the opening. In the case of the bottom emission type, the insulation substrate 110 is positioned at the front surface of the external case 500 (see FIG. 8), while, in the case of the top emission type, the upper insulation substrate 400 is positioned at the front surface of the external case 500 (see FIG. 9).

The size of the opening of the external case 500 and the size of the light emitting region 600 of the organic light emitting diode display are not consistent with each other. The size of the opening of the external case 500 is slightly larger than the size of the light emitting region 600 of the organic light emitting diode display.

When the optical film 550 is only formed at the front surface of the light emitting region 600, there is a problem in that external light is reflected in a space between the external case 500 and the light emitting region 600. Therefore, the display characteristics of the organic light emitting diode display are degraded. In a structure, such as a liquid crystal display, in which a black matrix is formed, since a black matrix absorbs light, it is not necessary to form an additional optical film between the external case and the light emitting region. However, in the organic light emitting diode display, since the black matrix is not formed, the optical film 550 needs to be formed between the external case 500 and the light emitting region 600.

In FIG. 7, a dotted line region indicates a periphery of the optical film 550. In FIGS. 8 and 9, dotted line regions indicate a peripheral edge of the light emitting region 600.

FIG. 8 shows a cross-sectional view of the bottom emission type organic light emitting diode display according to an exemplary embodiment of the present invention. FIG. 9 shows a cross-sectional view of the top emission type organic light emitting diode display according to another exemplary embodiment of the present invention.

FIG. 8 shows the bottom emission type organic light emitting diode display. The upper insulation substrate 400 is positioned at the inner bottom surface of the external case 500. The common electrode (not shown), the organic light emitting member (not shown), and the pixel electrode (not shown) are sequentially formed on the insulation substrate 400 so as to form the light emitting region 600. The lower insulation substrate 110 is formed on the light emitting region 600. The optical film 550 is adhered to the outer side surface of the lower insulation substrate 110. The external case 500 is formed to cover a portion of the optical film 550. Therefore, the optical film 550 is exposed to the outside through the opening of the external case 500. In this case, the common electrode is formed of a reflective metal and the pixel electrode is formed of a transparent conductive material.

FIG. 9 shows the top emission type organic light emitting diode display. The lower insulation substrate 110 is formed on the inner bottom surface of the external case 500. The pixel electrode (not shown), the organic light emitting member (not shown), the common electrode (not shown) are sequentially formed on the lower insulation substrate 110 so as to form the light emitting region 600. The upper insulation substrate 400 is formed on the light emitting region 600. The optical film 550 is adhered to the outer side surface of the upper insulation substrate 400. The external case 500 is formed to cover a portion of the optical film 550. Therefore, the optical film 550 is exposed to the outside through the opening of the external case 500. In this case, the pixel electrode is formed of the reflective metal and the common electrode is formed of the transparent conductive material.

The optical film 550 may be various types of films which include, for example, a polarization film, a low-reflective film, such as an anti-reflection film or anti-glare film, or a protective film, such as an anti-scratch film, that protects the organic light emitting diode display. These films may be formed in multiple layers.

Though not shown in FIGS. 8 and 9, an adhesive is formed between the insulation substrate 110 or 400 and the optical film 550 so as to adhere the insulation substrate 110 or 400 and the optical film 550. The adhesive may vary according to the kinds of the optical film 550.

As described above, the optical film is adhered between the opening of the external case and the light emitting region so as to prevent display quality of the organic light emitting diode display from being degraded. An impact is not directly delivered to the insulation substrate from the outside but is delivered after being absorbed by the optical film. Therefore, it is possible to safely protect the organic light emitting diode display.

While this invention has been described in connection with what is presently considered to be practical exemplary embodiments, it is to be understood that the present invention is not limited to the disclosed exemplary embodiments, but, on the contrary, is intended to cover various modifications and equivalent arrangements included within the spirit and scope of the appended claims.

What is claimed is:

1. An organic light emitting diode display comprising:
a first substrate;
first signal lines formed on the first substrate;
second signal lines formed on the first substrate;
switching thin film transistors connected to the first and second signal lines;
driving thin film transistors connected to the switching thin film transistors;
organic light emitting diodes connected to the driving thin film transistors;
a second substrate covering the organic light emitting diodes;
an optical film adhered to an outer surface of the first substrate or the second substrate; and
an external case covering a portion of the optical film.

2. The organic light emitting diode display of claim 1, wherein the optical film is a film having low reflectance.

3. The organic light emitting diode display of claim 1, wherein the optical film has two or more films formed in multiple layers.

4. The organic light emitting diode display of claim 1, wherein an adhesive is interposed between the optical film and the substrate adhered to the optical film.

5. The organic light emitting diode display of claim 1, wherein the optical film comprises a circular polarizer.

6. The organic light emitting diode display of claim 1, wherein light emitted in the organic light emitting diodes passes through the substrate adhered to the optical film.

7. The organic light emitting diode display of claim 1, wherein two or more organic light emitting diodes form a light emitting region where an image is displayed and the optical film is formed covering the light emitting region, and wherein the external case has an opening having an area larger than an area of the light emitting region and smaller than an area of the optical film.

8. An organic light emitting diode display comprising:
a first substrate;
first signal lines formed on the first substrate;
second signal lines formed on the first substrate;
switching thin film transistors connected to the first and second signal lines;
driving thin film transistors connected to the switching thin film transistors;
organic light emitting diodes connected to the driving thin film transistors;
a second substrate covering the organic light emitting diodes;
an optical film adhered to an upper surface of the second substrate; and
an external case covering a portion of the optical film.

9. The organic light emitting diode display of claim 7, wherein the optical film is a film having low reflectance.

10. The organic light emitting diode display of claim 9, wherein the optical film has two or more films formed in multiple layers.

11. The organic light emitting diode display of claim 7, wherein the second substrate and the optical film are adhered by an adhesive.

12. The organic light emitting diode display of claim 7, wherein each of the organic light emitting diodes includes a first electrode including a transparent conductive material on the light emitting side surface, a second electrode including a reflective metal on a side surface opposite to the light emitting side surface, and a light emitting member formed between the first electrode and the second electrode.

13. The organic light emitting diode display of claim 8, wherein two or more organic light emitting diodes form a light emitting region where an image is displayed and the optical film is formed covering the light emitting region.

14. The organic light emitting diode display of claim 13, wherein the external case has an opening having an area larger than an area of the light emitting region and smaller than an area of the optical film.

15. An organic light emitting diode display comprising:
a first substrate;
first signal lines formed on the first substrate;
second signal lines formed on the first substrate;
switching thin film transistors connected to the first and second signal lines;
driving thin film transistors connected to the switching thin film transistors;
first electrodes connected to the driving thin film transistors;
second electrodes facing the first electrodes;
light emitting members respectively formed between the first electrodes and the second electrodes;
a light emitting region in which the plurality of first electrodes, second electrodes, and light emitting members are formed so as to display images;
an optical film adhered to the bottom of the first substrate; and
an external case having an opening,
wherein the external case covers a portion of the optical film.

16. The organic light emitting diode display of claim 15, wherein the opening is formed so as to expose the optical film.

17. The organic light emitting diode display of claim 15, wherein the opening is larger than an area of the light emitting region and smaller than an area of the optical film.

18. The organic light emitting diode display of claim 15, wherein the optical film is a film having low reflectance.

19. The organic light emitting diode display of claim 18, wherein the optical film has two or more films formed in multiple layers.

20. The organic light emitting diode display of claim 15, wherein the first substrate and the optical film are adhered by an adhesive.
